(19) United States
(12) Patent Application Publication
(10) Pub. No.: US 2025/0279757 A1
(43) Pub. Date: Sep. 4, 2025

(54) SWITCHED CAPACITOR CIRCUIT

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: Shotaro WADA, Nisshin-shi (JP); Tomohiro NEZUKA, Nisshin-shi (JP); Yoshikazu FURUTA, Nisshin-shi (JP)

(21) Appl. No.: 19/018,026

(22) Filed: Jan. 13, 2025

(30) Foreign Application Priority Data
Mar. 4, 2024 (JP) 2024-032179

(51) Int. Cl. H03F 3/45; H03M 3/00

(52) U.S. Cl. CPC H03F 3/45753; H03M 3/34; H03F 2200/144; H03F 2200/264; H03F 2200/267; H03F 2200/42; H03F 2200/421

(57) ABSTRACT

A switched capacitor circuit includes main, common-mode feedback, and control circuits. The main circuit includes a sampling capacitor and an operational amplifier. The sampling capacitor samples an input signal with first and second control signals. The common-mode feedback circuit includes: a first capacitor connected between an output of the operational amplifier and a node; a second capacitor connected in parallel to the first capacitor via a first switch group; a third capacitor connected in parallel to the first capacitor via a second switch group; and a third switch group and a fourth switch group. The control circuit turns on the first switch group and the fourth switch group in synchronization with a first common control signa based on the first control signal, and turns on the second switch group and the third switch group in synchronization with a second common control signa based on the second control signal.

### CROSS REFERENCE TO RELATED APPLICATION

This application is based on Japanese Patent Application No. 2024-032179 filed on Mar. 4, 2024, the disclosure of which is incorporated herein by reference.

### TECHNICAL FIELD

The present disclosure relates to a switched capacitor circuit.

### BACKGROUND

A delta-sigma modulator may have a capacitive differential amplifier circuit for an analog differential signal by amplifying an analog signal in proportion to a ratio between a first capacitance and a second capacitance of a capacitive differential circuit, and the analog signal amplified by the capacitive differential amplifier circuit may be integrated by an integrator. Further, the delta-sigma modulator may generate a digital output signal based on an analog differential signal amplified by a capacitive differential amplifier circuit.

### SUMMARY

The present disclosure describes a switched capacitor circuit including a main circuit and a control circuit.

### BRIEF DESCRIPTION OF DRAWINGS

FIG. 1 is an electrical configuration diagram of a common-mode feedback circuit in a first embodiment.

FIG. 2 is an electrical configuration diagram of a switched capacitor circuit in the first embodiment.

FIG. 3 is a timing chart of control signals provided to switches in the first embodiment.

FIG. 4 is an electrical configuration diagram of a common-mode feedback circuit in a comparative example.

FIG. 5 is a diagram showing the relationship of operating frequencies for each circuit stage in a second embodiment.

FIG. 6 is an explanatory diagram of the operation of the common-mode feedback circuit in the second embodiment.

FIG. 7 is a diagram showing the relationship of operating frequencies for respective circuit stages in the comparative example.

FIG. 8 is an explanatory diagram of the operation of the common-mode feedback circuit in the comparative example.

FIG. 9 is an electrical configuration diagram of the switched capacitor circuit in a third embodiment.

FIG. 10 is an electrical configuration diagram of the common-mode feedback circuit of the second operational amplifier in the third embodiment.

FIG. 11 is a timing chart schematically showing the changes in signals at various parts in the third embodiment.

FIG. 12 is a correspondence diagram of control signals provided to respective switches in the third embodiment.

FIG. 13 is an electrical configuration diagram of the switched capacitor circuit in a fourth embodiment.

FIG. 14 is a correspondence diagram of the control signals provided to respective switches in the fourth embodiment.

FIG. 15 is a timing chart schematically showing the changes in signals at various parts in the fourth embodiment.

FIG. 16 is an electrical configuration diagram of the switched capacitor circuit in a fifth embodiment.

FIG. 17 is a correspondence diagram of control signals provided to respective switches in the fifth embodiment.

FIG. 18 is a timing chart schematically showing the changes in signals at various parts in the fifth embodiment.

FIG. 19 is a timing chart schematically showing the changes in signals at various parts in a sixth embodiment.

### DETAILED DESCRIPTION

In a comparative example, when the common-mode feedback circuit is switched, the switch connection as seen from the output side of the operational amplifier changes. As a result, the capacitance value as seen from the common-mode feedback circuit side varies within one cycle, causing the output potential of the operational amplifier to fluctuate easily.

According to an aspect of the present disclosure, a switched capacitor circuit includes a main circuit and a control circuit. The main circuit includes a sampling capacitor, a common-mode feedback circuit, and an operational amplifier. The sampling capacitor samples an input signal by turning on an input chopping switch with a first control signal and a second control signal, and the first control signal and the second control signal are different from each other.

The common-mode feedback circuit includes: a first capacitor that is connected between an output of the operational amplifier and a node to which a current-biasing potential is applied from the operational amplifier; a second capacitor that is connected in parallel to the first capacitor via a first switch group; a third capacitor that is connected in parallel to the first capacitor via a second switch group; and a third switch group and a fourth switch group that apply an output common-mode reference potential and a current-biasing reference potential of the first operational amplifier to the second capacitor and the third capacitor, respectively.

The control circuit turns on the first switch group and the fourth switch group in synchronization with a first common control signal provided based on the first control signal, and turns on the second switch group and the third switch group in synchronization with a second common control signal provided based on the second control signal. At this time, a value of total connected capacitance acquired by connecting the output of operational amplifier to one of the first capacitor, the second capacitor, and the third capacitor of the common-mode feedback circuit is same in both of a timing in which the first common control signal is at an on-level and a timing in which the second common control signal is at an on-level.

According to the above configuration, the value of the total connected capacitance on the common-mode feedback circuit side as seen from the output side of the operational amplifier can be made the same regardless of a phase in which the first common control signal is at an on-level and a phase in which the second common control signal is at an on-level. This allows for the elimination of errors caused by asymmetry between the respective phases.

The following is a description of several embodiments of the switched capacitor circuit with reference to the drawings. In each embodiment, substantially identical or similar parts are designated by the same or similar reference numerals, and descriptions are omitted as necessary. Each embodiment focuses on explaining the characteristic parts. Furthermore, in the following embodiments, differential circuits are used for explanation. Subscripts ‘a’ and ‘b’ are attached to the circuit components with symmetrical differential configurations, and these are illustrated in the figures. As necessary, subscripts with parentheses, such as (S1a, S1b), may be added for clarification, or the subscripts ‘a’ and ‘b’ may be omitted in the description.

### First Embodiment

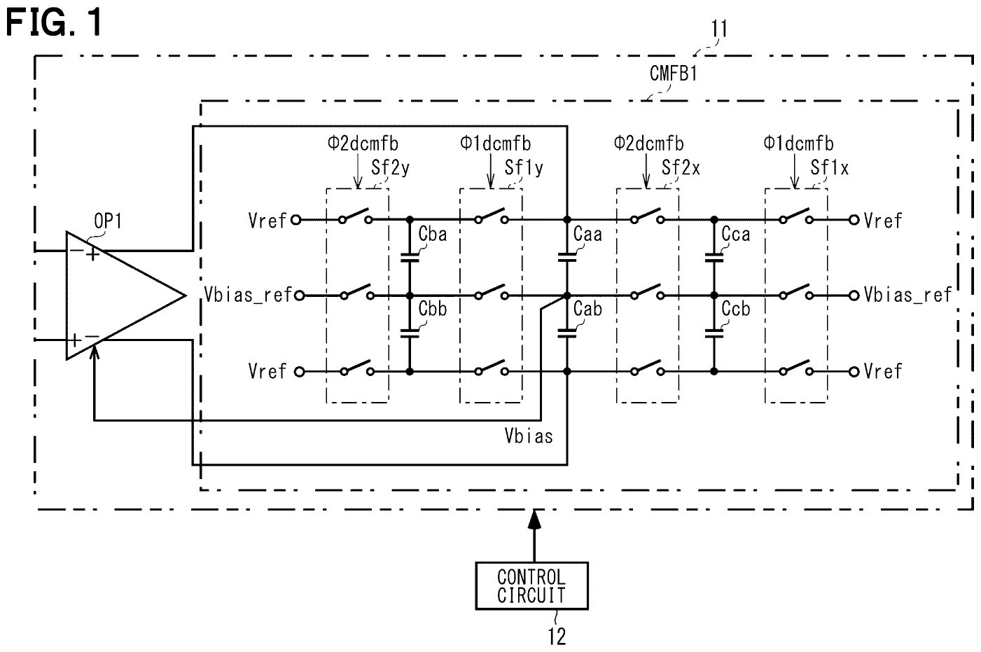

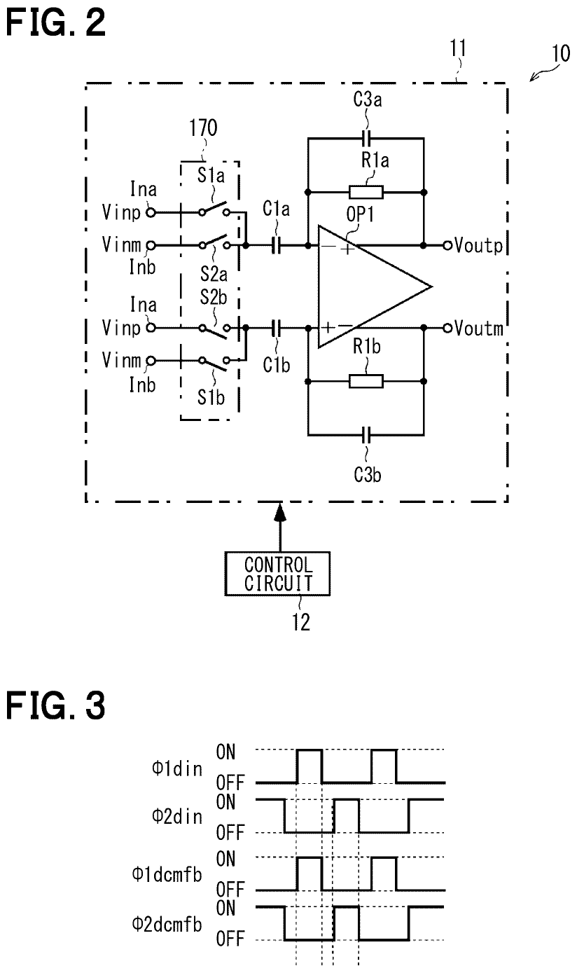

A first embodiment will be described with reference to FIGS. 1 to 4. As shown in FIG. 2, a switched capacitor circuit 10 includes a capacitive coupling amplifier 11 and a control circuit 12. The control circuit 12 includes a microcomputer or a logic circuit, and outputs control signals to the switches S1 (S1a, S1b) and S2 (S2a, S2b) that are included in the switched capacitor circuit 10, thereby turning them on and off. The switches S1 (S1a, S1b) and S2 (S2a, S2b) are included in an input chopping switch 170.

The capacitive coupling amplifier 11, which serves as the main circuit unit (may also be simply referred to as a main circuit), primarily includes a fully differential first operational amplifier OP1. The capacitive coupling amplifier 11 is constructed by connecting a parallel circuit of resistors R1 (R1a, R1b) and feedback capacitors C3 (C3a, C3b) between the input and output of the first operational amplifier OP1. The resistors R1 (R1a, R1b) are provided to determine the input voltage of the first operational amplifier OP1. Additionally, between the input terminals Ina, Inb and the inverting and non-inverting input terminals of the first operational amplifier OP1, capacitors C1 (C1a, C1b), are connected respectively. The capacitors C1 (C1a, C1b) serve as sampling capacitors. The differential analog input signals Vinp and Vinm are provided to the capacitive coupling amplifier 11 through the input terminals Ina and Inb. At this time, a voltage of about “Vinp−Vinm=±100 mV” is applied.

Further, switches S1a and S2b are interposed and connected between the input terminal Ina and the inverting input terminal and the non-inverting input terminal of the first operational amplifier OP1, respectively. Switches S2a and S1b are interposed and connected between the input terminal Inb and the inverting input terminal and the non-inverting input terminal of the first operational amplifier OP1, respectively. By turning the input chopping switch 170 on and off, the control circuit 12 can invert the polarity of the analog input signals Vinp and Vinm and provide them to the first operational amplifier OP1. The switches S1a, S1b, S2a, and S2b are connected between the input of the capacitive coupling amplifier 11 and the capacitors C3a and C3b. No switch is interposed between the input and output of the first operational amplifier OP1.

The sampling capacitors C1 (C1a, C1b) sample the analog input signals Vinp and Vinm when the switches S1 (S1a, S1b) and S2 (S2a, S2b) are turned on by different first control signal ϕ1din and second control signal ϕ2din, respectively. In the example shown in FIG. 3, the control circuit 12 turns on the switches S1 (S1a, S1b) with the first control signal ϕ1din and turns on the switches S2 (S2a, S2b) with the second control signal ϕ2din.

As shown in FIG. 1, the capacitive coupling amplifier 11 includes a first common-mode feedback circuit CMFB1 at the output of the first operational amplifier OP1. The first common-mode feedback circuit CMFB1 includes a first capacitor group Ca having capacitors Caa, Cab (hereinafter may be collectively referred to as the first capacitor Ca (Caa, Cab)), a second capacitor group Cb having capacitors Cba, Cbb (hereinafter may be collectively referred to as the second capacitor Cb (Cba, Cbb)), and a third capacitor group Cc having capacitors Cca, Ccb (hereinafter may be collectively referred to as the third capacitor Cc (Cca, Ccb)), along with a first switch group Sf1y, a second switch group Sf2x, a third switch group Sf2y, and a fourth switch group Sf1x.

The first capacitor Ca (Caa, Cab) is connected between the output of the first operational amplifier OP1 and the supply node of the potential for current biasing Vbias of the first operational amplifier OP1. The second capacitor Cb (Cba, Cbb) is connected in parallel with the first capacitor Ca (Caa, Cab) via the first switch group Sf1y. The third capacitor Cc (Cca, Ccb) is connected in parallel with the first capacitor group Ca (Caa, Cab) via the second switch group Sf2x. In the present disclosure, the potential for current biasing Vbias may also be referred to as a voltage for current biasing or a current-biasing potential.

When the third switch group Sf2y is turned on by the control circuit 12, the third switch group Sf2y applies the output common-mode reference potential Vref and the reference potential for current biasing Vbias_ref of the first operational amplifier OP1 to the second capacitor Cb (Cba, Cbb). When the fourth switch group Sf1x is turned on by the control circuit 12, the fourth switch group Sf1x applies the output common-mode reference potential Vref and the reference potential for current biasing Vbias_ref of the first operational amplifier OP1 to the third capacitor Cc (Cca, Ccb). The reference potential for current biasing Vbias_ref may also be referred to as a reference voltage for current biasing or a current-biasing reference potential in the present disclosure. The output common-mode reference potential Vref may also be referred to as an output common-mode reference voltage in the present disclosure.

The control circuit 12 turns on the first switch group Sf1y and the fourth switch group Sf1x in synchronization with the first common control signal ϕ1dcmfb, which is provided depending on the first control signal ϕ1din. The first control signal ϕ1din and the first common control signal ϕ1dcmfb are considered to be dependent on each other; however, as shown in FIG. 3, they may be the same control signal, or the first common control signal ϕ1dcmfb may be set to half or twice the frequency of the first control signal ϕ1din. In this case, they may be synchronized.

The control circuit 12 turns on the second switch group Sf2x and the third switch group Sf2y in synchronization with the second common control signal ϕ2dcmfb, which is provided depending on the second control signal ϕ2din. The second control signal ϕ2din and the second common control signal ϕ2dcmfb are considered to be dependent on each other; however, as shown in FIG. 3, they may be the same control signals, or the second common control signal ϕ2dcmfb may be set to half or twice the frequency of the second control signal ϕ2din. In this case, they may be synchronized.

As shown in FIG. 3, the operation of the capacitive coupling amplifier 11 will be explained when the first control signal ϕ1din and the first common control signal ϕ1dcmfb are the same control signals, and the second control signal ϕ2din and the second common control signal ϕ2dcmfb are the same control signals.

### First Control Signal ϕ1din, First Common Control Signal ϕ1dcmfb: ON

As shown in FIG. 3, when the first control signal ϕ1din is turned to the on-level, the control circuit 12 simultaneously turns the first common control signal ϕ1dcmfb to the on-level. At this time, when the switch S1 (S1a, S1b) is turned on, the analog input signals Vinp and Vinm are sampled by the sampling capacitor C1 (C1a, C1b). The term “on-level” may also be referred to as an “on-state” in the present disclosure.

At the same time, since the first switch group Sf1y shown in FIG. 1 is turned on while the second switch group Sf2x and the third switch group Sf2y are turned off, the first capacitor Ca (Caa, Cab) and the second capacitor Cb (Cba, Cbb) are connected in parallel, and charge distribution occurs. As described later, when the second control signal ϕ2din is at an on-level, a constant differential voltage between the reference potential for current biasing Vbias_ref and the output common-mode reference potential Vref is applied to the second capacitor Cb (Cba, Cbb).

Therefore, when the first control signal ϕ1din is turned to the on-level and charge distribution occurs, the potential for current biasing Vbias approaches the reference potential for current biasing Vbias_ref, and the output common-mode of the first operational amplifier OP1 approaches the output common-mode reference potential Vref. Since the fourth switch group Sf1x is turned on, the differential voltage between the reference potential for current biasing Vbias_ref and the output common-mode reference potential Vref is applied to the third capacitor Cc (Cca, Ccb). As a result, the voltage between the terminals of the third capacitor Cc (Cca, Ccb) stabilizes.

### Second Control Signal ϕ2din, Second Common Control Signal ϕ2dcmfb: BOTH ON

As shown in FIG. 3, when the second control signal ϕ2din is turned to the on-level, the control circuit 12 simultaneously turns the second common control signal ϕ2dcmfb to the on-level. At this time, by turning on the switch S2 (S2a, S2b), charge is drawn from the sampling capacitor C1 (C1a, C1b) to the input terminals Ina and Inb. As a result, charge transfer occurs, and the analog input signals Vinp and Vinm are amplified by the operation of the first operational amplifier OP1, the resistor R1 (R1a, R1b), and the feedback capacitor C3 (C3a, C3b).

At the same time, the third switch group Sf2y shown in FIG. 1 is turned on while the fourth switch group Sf1x and the first switch group Sf1y are turned off, so that the first capacitor Ca (Caa, Cab) and the third capacitor Cc (Cca, Ccb) are connected in parallel for charge distribution. When the first control signal ϕ1din is at the on-level as described above, the third capacitor Cc (Cca, Ccb) is given a constant difference voltage between the reference potential Vbias_ref for bias current and the output common-mode reference potential Vref. Therefore, when the second control signal ϕ2din is turned to the on-level and charge distribution occurs, the potential for current biasing Vbias approaches the reference potential for current biasing Vbias_ref, and the output common-mode of the first operational amplifier OP1 approaches the output common-mode reference potential Vref. Since the third switch group Sf2y is turned on, the second capacitor Cb (Cba, Cbb) is given the differential voltage between the reference potential Vbias_ref for bias current and the output common-mode reference potential Vref. This stabilizes the voltage between the respective terminals of the second capacitor Cb (Cba, Cbb).

The first phase in which the first control signal ϕ1din is turned to the on-level and the second phase in which the second control signal ϕ2din is turned to the on-level are repeated. In this case, even if the connection states of the respective switch groups Sf1y, Sf2x, Sf2y, and Sf1x are changed in each of the first common phase where the first common control signal ϕ1dcmfb is turned the on-level and the second common phase where the second common control signal ϕ2dcmfb is turned to the on-level, the connection configuration of the first capacitor Ca (Caa, Cab), the second capacitor Cb (Cba, Cbb), and the third capacitor Cc (Cca, Ccb) as viewed from the output side of the first operational amplifier OP1 will be the same.

Therefore, when the first common control signal ϕ1dcmfb is at the on-level and when the second common control signal ϕ2dcmfb is at the on-level, the total value of the connected capacitance between the output of the first operational amplifier OP1 and any of the first capacitor Ca (Caa, Cab), the second capacitor Cb (Cba, Cbb), and the third capacitor Cc (Cca, Ccb) of the first common-mode feedback circuit CMFB1 becomes equal. As a result, when the capacitive coupling amplifier 11 amplifies the input signals Vinp and Vinm, it is possible to prevent the capacitance value on the output side of the first operational amplifier OP1 from changing during both the phase when the first control signal ϕ1din is at the on-level and the phase when the second control signal ϕ2din is at the on-level, thereby eliminating errors caused by asymmetry between the respective phases.

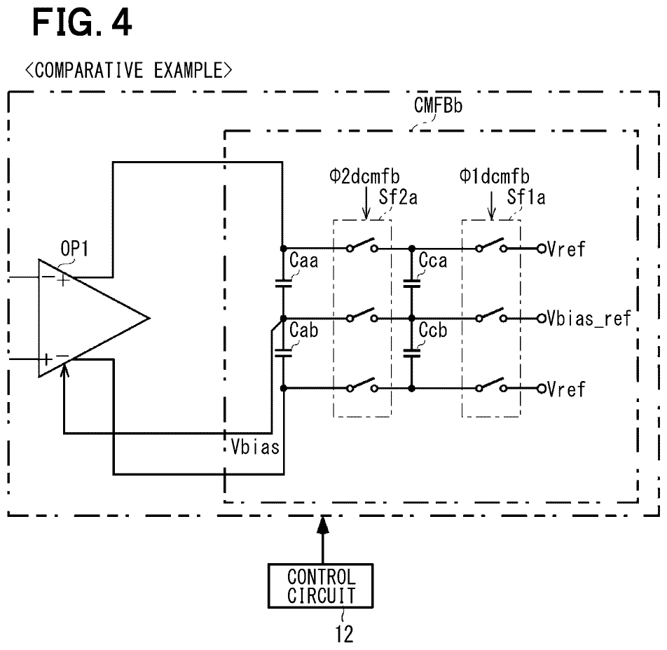

FIG. 4 shows a comparative example of the common-mode feedback circuit CMFBb. As shown in FIG. 4, when only the first capacitor Ca (Caa, Cab) is connected to the third capacitor Cc (Cca, Ccb), the total capacitance value as seen from the output side of the first operational amplifier OP1 becomes different and unbalanced between the first phase in which the first control signal ϕ1din is at the on-level, and the second phase in which the second control signal ϕ2din is at the on-level, due to the repetition of these phases. As a result, they are subject to errors caused by asymmetries between the respective phases.

According to the configuration of the present embodiment, in both the first common phase in which the first common control signal ϕ1dcmfb is at the on-level and the second common phase in which the second common control signal ϕ2dcmfb is at the on-level, the total value of the connected capacitance between the output of the first operational amplifier OP1 and any of the first capacitor Ca (Caa, Cab), the second capacitor Cb (Cba, Cbb), and the third capacitor Cc (Cca, Ccb) of the first common-mode feedback circuit CMFB1 is made to be the same. This allows for the elimination of errors caused by asymmetry between the respective phases.

### Second Embodiment

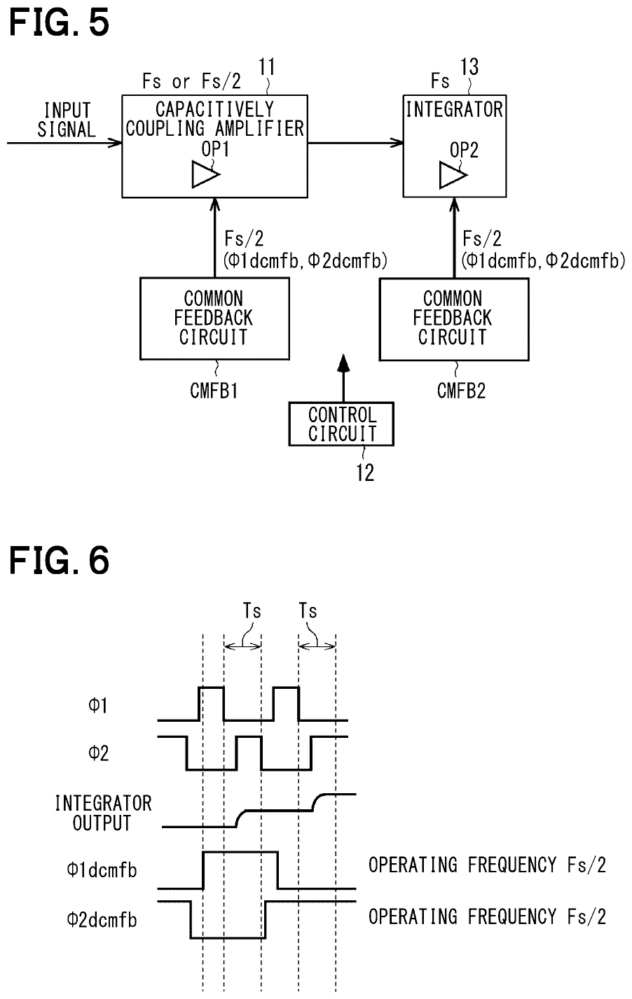

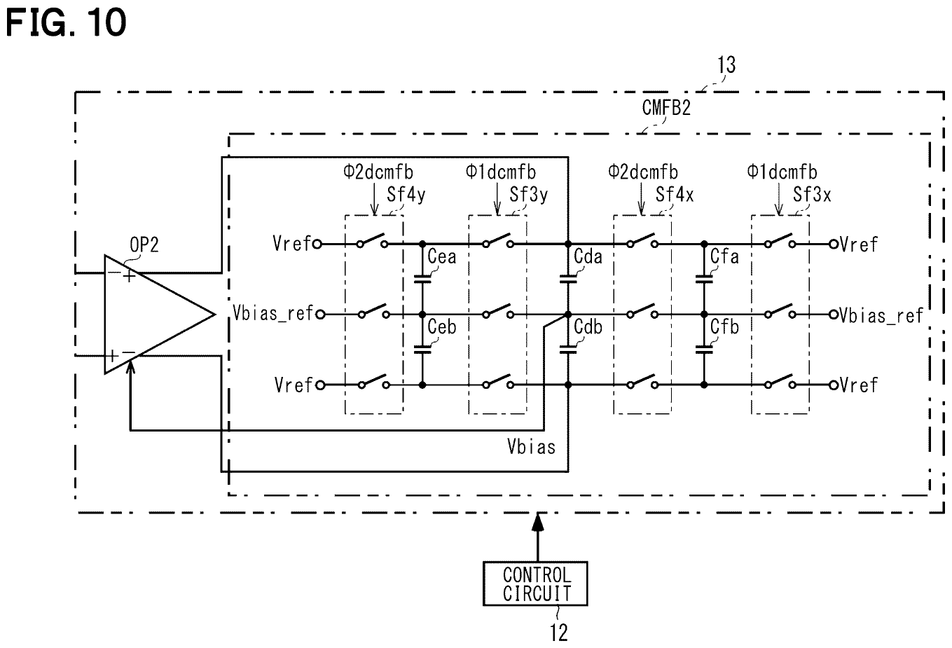

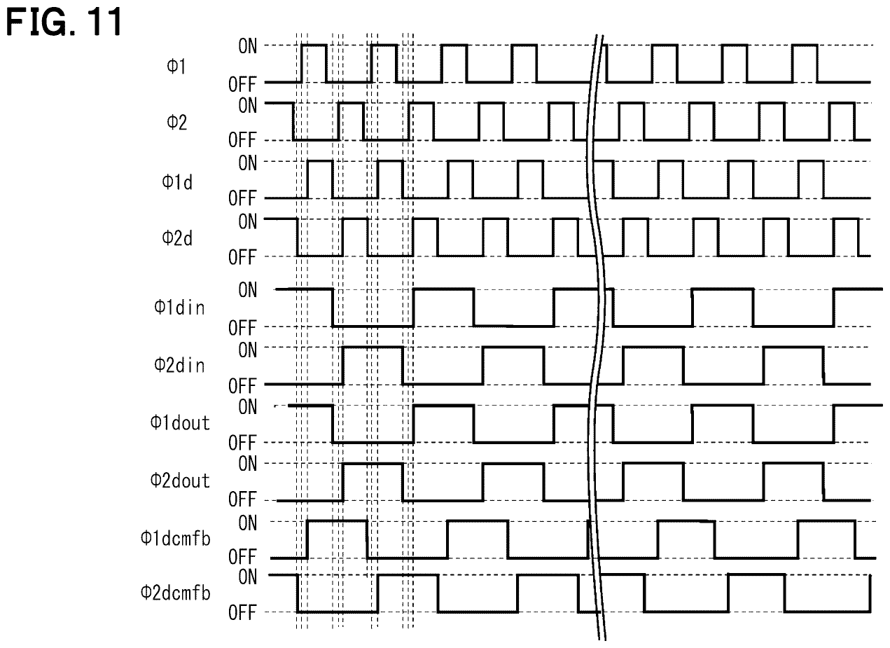

The second embodiment will be described with reference to FIGS. 5 to 8. As shown in FIG. 5, an integrator 13 is connected after the capacitive coupling amplifier 11. The integrator 13 is a switched-capacitor type integrator, which is constructed by combining a second operational amplifier OP2 with switches and capacitors (not shown). The output of the second operational amplifier OP2, which is included in the integrator 13, is connected to a second common-mode feedback circuit CMFB2 that has the same configuration as the aforementioned first common-mode feedback circuit CMFB1. The second common-mode feedback circuit CMFB2 has the same configuration as that shown in FIG. 10, which will be described in the third embodiment. However, the explanation is omitted here.

The capacitive coupling amplifier 11 amplifies the analog input signals Vinp and Vinm by charging and discharging the capacitors C1 and C3 through the on-off operation of the input chopping switch 170 at a frequency Fs/2, which is half of the reference frequency Fs. At this time, the integrator 13 is also constructed to integrate the output of the capacitive coupling amplifier 11 by charging and discharging the capacitors through the on-off operation of the constituent switches (not shown) at the reference frequency Fs.

When the switched capacitors of the integrator 13 perform the integration process by charging and discharging, it is not desirable to operate the first common-mode feedback circuit CMFB1 and the second common-mode feedback circuit CMFB2, because doing so would cause fluctuations in the output potentials of the first operational amplifier OP1 and the second operational amplifier OP2. Therefore, the control circuit 12 controls the system such that at least the common-mode feedback circuits CMFB1 and CMFB2 are not operated during the integration period Ts, during which the output of the capacitive coupling amplifier 11 is integrated by the integrator 13. For example, the control circuit 12 operates the common-mode feedback circuits CMFB1 and CMFB2 using a clock signal at a frequency Fs/2, which is one-half of the reference frequency Fs, when the integrator 13 is operated using the clock signal of the reference frequency Fs.

As shown in FIG. 6, during the integration period Ts, neither the first common control signal ϕ1dcmfb nor the second common control signal ϕ2dcmfb changes, and none of the switches in the groups Sf1y, Sf2x, Sf2y, or Sf1x are switching. As a result, during the timing when the integrator 13 performs the integration process, the first common-mode feedback circuit CMFB1 and the second common-mode feedback circuit CMFB2 do not operate. This allows the integration process to be carried out with minimal fluctuation in the output common potentials of the first operational amplifier OP1 and the second operational amplifier OP2.

The control circuit 12 allows the operation of the common-mode feedback circuits CMFB1 and CMFB2 during periods other than the integration period Ts. This is because, if it is not the integration period Ts, fluctuations in the output potential of the second operational amplifier OP2 do not affect the integration result.

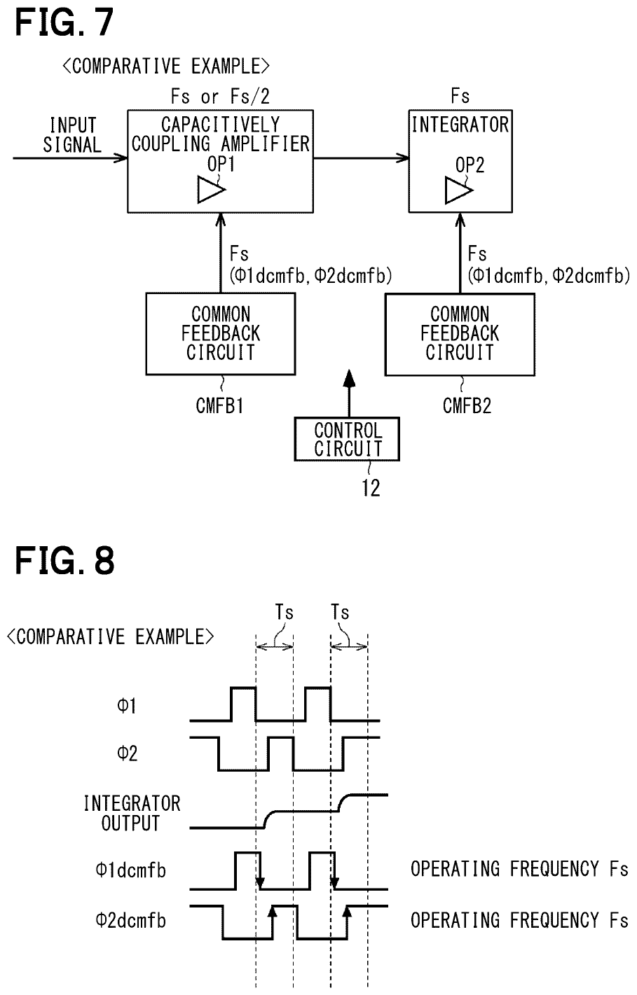

A comparative example is shown in FIG. 7, and its operation is illustrated in FIG. 8. As shown in FIG. 7, if the capacitive coupling amplifier 11, the integrator 13, and the common-mode feedback circuits CMFB1 and CMFB2 are operated at the same frequency, then, as illustrated in FIG. 8, during the charge transfer of the integration period Ts where the integrator 13 performs integration, the first common control signal ϕ1dcmfb switches from the on-level to the off-level and the second common control signal ϕ2dcmfb switches from the off-level to the on-level (refer to the arrowed portions shown in FIG. 8). The “off-level” may also be referred to as an “off-state” in the present disclosure.

As a result, if the common-mode feedback circuits CMFB1 and CMFB2 operate during the integration period Ts, the output potentials of the first operational amplifier OP1 and the second operational amplifier OP2 may fluctuate, which could lead to the integration process not being performed accurately. In contrast, in this embodiment, since the second common-mode feedback circuit CMFB2 does not operate during the integration period Ts, charge transfer can be executed more accurately, and the integration result can be obtained correctly.

For example, the control circuit 12 may operate the capacitive coupling amplifier 11 by a clock signal of the reference frequency Fs. Additionally, the first common-mode feedback circuit CMFB1 may be operated at a frequency Fs/2, which is half of the reference frequency Fs, and the second common-mode feedback circuit CMFB2 may also be operated at a frequency Fs/2.

### Third Embodiment

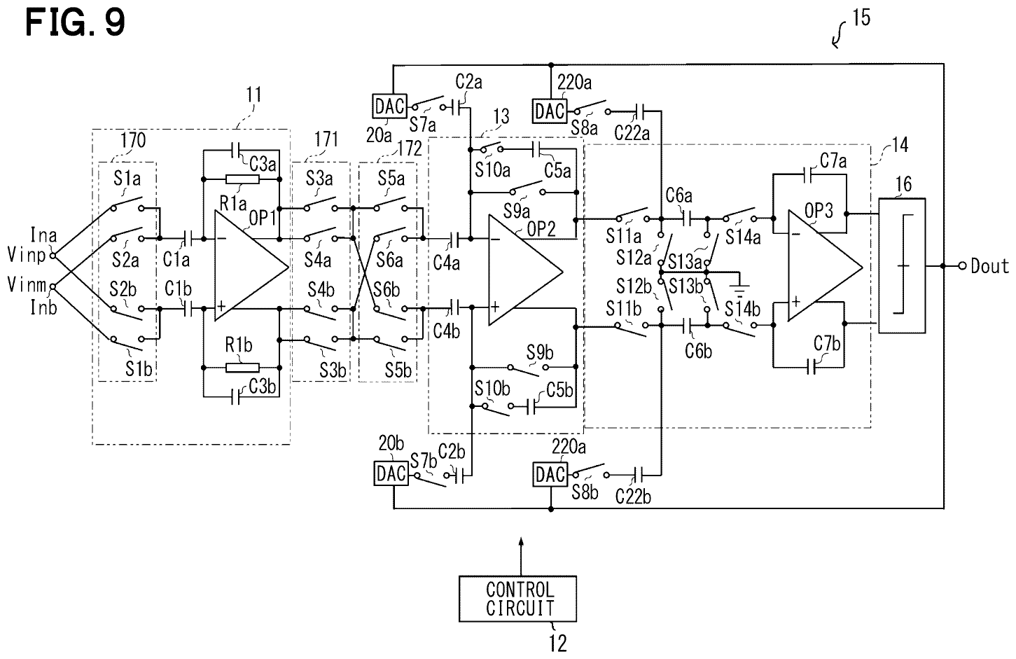

The following describes a third embodiment with reference to FIGS. 9 to 12. In the third embodiment and subsequent embodiments, more specific examples of the first embodiment or the second embodiment will be provided and explained. The same reference numerals are used for parts that have the same functions as in the first and second embodiments, and their explanations are omitted. The explanation will focus on the different parts.

FIG. 9 shows a schematic configuration of the delta-sigma (ΔΣ) modulator 15. The delta-sigma modulator 15 is a switched capacitor circuit having the capacitive coupling amplifier 11, the control circuit 12, the first integrator 13, and the second integrator 14. A quantizer 16 is provided at the output stage of the second integrator 14. The delta-sigma modulator 15 executes feedback of the output of the quantizer 16 to the first integrator 13 through D/A converters 20a and 20b, and executes feedback of the output of the quantizer 16 to the second integrator 14 through D/A converters 220a and 220b.

The control circuit 12 outputs control signals to the capacitive coupling amplifier 11, the first integrator 13, the second integrator 14, the quantizer 16, the D/A converters 20a and 20b, and 220a and 220b. The differential input signals Vinp and Vinm are provided to the capacitive coupling amplifier 11 through the input terminals Ina and Inb. At the input of the capacitive coupling amplifier 11, the switches S1a, S1b, S2a, and S2b are constructed as the input chopping switch 170 as described in the previous embodiment. The capacitive coupling amplifier 11 amplifies the differential input signals Vinp and Vinm as described in the first embodiment. The capacitive coupling amplifier 11 amplifies the input signals Vinp and Vinm by charging and discharging the capacitors C1 and C3 when the input chopping switch 170 is turned on and off at a frequency Fs/2 being one-half of the reference frequency Fs. The operational amplifier OP1 of the capacitive coupling amplifier 11 is connected to the first common-mode feedback circuit CMFB1, which operates at a frequency Fs/2 being one-half of the reference frequency Fs.

The first integrator 13 is constructed at the rear stage of the capacitive coupling amplifier 11. The first output chopping switch 171 is connected between the capacitive coupling amplifier 11 and the integrator 13. The second output chopping switch 172 is connected between the first output chopping switch 171 and the input of the integrator 13. These first output chopping switch 171 and second output chopping switch 172 indicate switches that toggle the output polarity of the capacitive coupling amplifier 11 between normal and inverted.

The first integrator 13 is constructed as a correlated double sampling (CDS) type, and includes a fully differential second operational amplifier OP2, a series circuit of feedback capacitors C5a, C5b and feedback switches S10a, S10b connected between the input and output of the second operational amplifier OP2, and reset switches S9a, S9b connecting the input and output of the second operational amplifier OP2. The switching between charging and discharging of capacitors C5a and C5b can be done using the switches S10a and S10b.

As shown in FIG. 10, the first integrator 13 includes a second common-mode feedback circuit CMFB2 at the output of the second operational amplifier OP2. The second common-mode feedback circuit CMFB2 includes a fourth capacitor group having capacitors Cda, Cdb connected between the output of the second operational amplifier OP2 and the potential for current biasing Vbias of the second operational amplifier OP2, and a fifth capacitor group having capacitors Cea, Ceb connected in parallel to the fourth capacitor group Cda, Cdb via a fifth switch group Sf3y. The fourth capacitor group may be collectively referred to as a fourth capacitor Cda, Cdb in the present disclosure. The fifth capacitor group may be collectively referred to as a fifth capacitor Cea, Ceb in the present disclosure.

The second common-mode feedback circuit CMFB2 includes a sixth capacitor group having capacitors Cfa, Cfb connected in parallel to the fourth capacitor Cda, Cdb via a sixth switch group Sf4x. The sixth capacitor group may be collectively referred to as a sixth capacitor Cfa, Cfb in the present disclosure. The second common-mode mode feedback circuit CMFB2 includes a seventh switch group Sf4y and an eighth switch group Sf3x, which respectively apply the output common-mode reference potential Vref and the reference potential for current biasing Vbias_ref of the second operational amplifier OP2 to the fifth capacitor Cea, Ceb and the sixth capacitor Cfa, Cfb.

The control circuit 12 operates the first integrator 13 using a clock signal of a reference frequency Fs, and it operates the second common-mode feedback circuit CMFB2 of the first integrator 13 using a clock signal with a frequency (for example, Fs/2) that is one-half of the reference frequency. In this case, the second common-mode feedback circuit CMFB2 of the first integrator 13 is operated using a clock signal with a frequency (for example, Fs/2) that is half of the reference frequency. However, it may also be operated using a clock signal with the reference frequency Fs.

The output of the first integrator 13 is provided to the second integrator 14. The second integrator 14 also mainly includes a fully differential third operational amplifier OP3. The output of the second operational amplifier OP2 is connected to the input of the third operational amplifier OP3 via the capacitors C6a and C6b. Further, switches S11a, S11b, S12a, S12b, S13a, S13b, S14a, and S14b are connected to each other between the output of the second operational amplifier OP2 and the input of the third operational amplifier OP3 in an illustrated manner.

These switches S11 to S14 are switched when charging a feedback capacitor C5 of the first integrator 13 to the capacitor C6 of the second integrator 14 or when discharging the capacitor C6.

A feedback capacitor C7 is connected between the input and output of the third operational amplifier OP3. The switches S14a and S14b indicate switches that can be switched when the feedback capacitor C7 is charged from the capacitor C6. The output of the third operational amplifier OP3 is connected to the input of the quantizer 16.

The quantizer 16 converts the output of the second integrator 14 into a digital signal Dout through level conversion. Further, the digital signal Dout of the quantizer 16 is provided to the D/A converters 20a, 20b, 220a and 220b. The D/A converters 20a and 20b execute feedback to the first integrator 13 based on the the digital signal Dout output from the quantizer 16. The D/A converters 20a and 20b are circuits that output a potential based on the digital signal Dout.

The switches S7a and S7b and the capacitors C2a and C2b are connected in series between the D/A converters 20a and 20b and the input of the second operational amplifier OP2 constituting the first integrator 13, and, when the control circuit 12 turns on the switches S7a and S7b, the D/A converters 20a and 20b execute feedback to the first integrator 13.

The D/A converters 220a and 220b execute feedback to the second integrator 14 based on the digital signal Dout output from the quantizer 16. The D/A converters 220a and 220b are circuits that output potential based on the digital signal Dout.

The switches S8a and S8b and the capacitors C6a and C6b are connected in series between the D/A converters 220a and 220b and the input of the operational amplifier OP2 included in the second integrator 14, and, when the control circuit 12 turns on the switches S8a and S8b, the D/A converters 220a and 220b execute feedback to the second integrator 14.

The following describes a control signal generated by the control circuit 12 in the present embodiment. The control circuit 12 includes a master clock generator using, for example, a crystal oscillator, a frequency divider, a synchronization circuit, an on-off edge generator, and a clock generator.

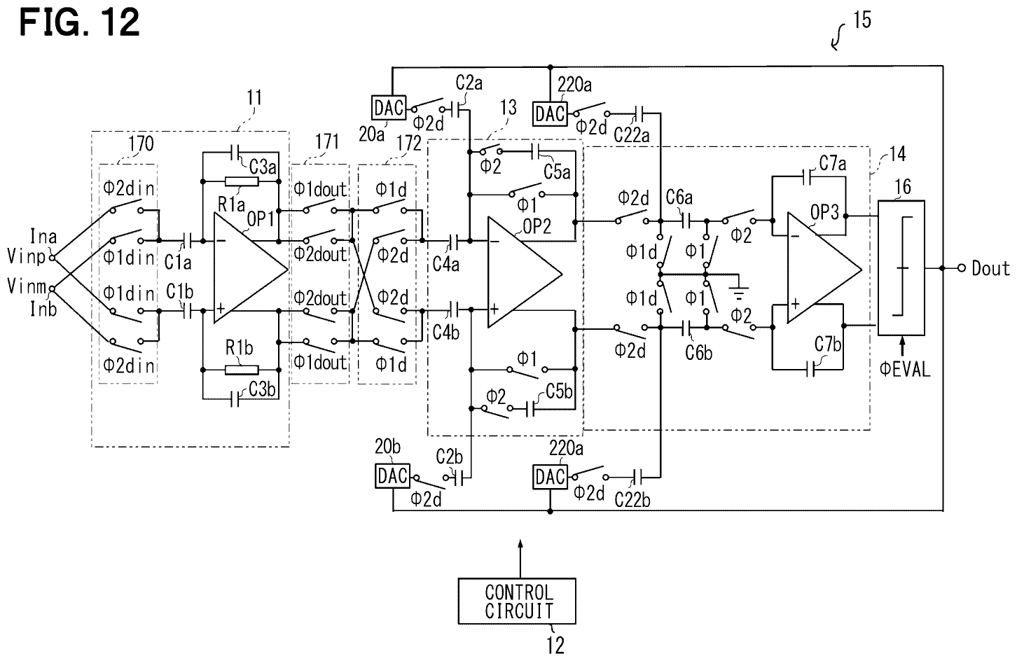

FIG. 11 illustrates the control signals ϕ1, ϕ2, ϕ1din, ϕ1dout, ϕ2din, and ϕ2dout to be provided to the aforementioned switches, and FIG. 12 shows correspondingly which switches are provided with the control signals ϕ1, ϕ2, ϕ1din, ϕ1dout, ϕ2din, and ϕ2dout.

The control signals ϕ1 and ϕ2 are controls signals for complementary turning on/off, and the control signals ϕ1d and ϕ2d are also control signals for complementary turning on/off. That is, the control signal 1 and the control signal ϕ2 are non-overlapping, and the control signal ϕ1d and the control signal ϕ2d are also non-overlapping. Further, the control signals ϕ1d and ϕ2d are control signals output so as to be slightly delayed as compared with the control signals ϕ1 and ϕ2.

Additionally, the control signals ϕ1din, ϕ1dout, ϕ2din, and ϕ2dout are control signals with one-half-cycle relative to the control signals ϕ1d and ϕ2d.

As shown in FIGS. 11, 12, the control circuit 12 outputs the control signals ϕ1, ϕ2, ϕ1d, ϕ1din, ϕ1dout, ϕ2d, ϕ2din and ϕ2d to the target switches S1a, S1b to S15a, and S15b to turn on and off the switches S1a, S1b to S15a, and S15b.

As shown in FIG. 11, when the frequencies of the control signals ϕ1, ϕ2, ϕ1d, and ϕ2d are taken as the reference frequency Fs, the control signals ϕ1din, ϕ2din, ϕ1dout, and ϕ2dout will have a frequency of Fs/2, which is half of the reference frequency Fs. Therefore, when the control circuit 12 drives the first integrator 13 with the first control signal ϕ1 at the predetermined phase timing of the reference frequency Fs, it performs a chopping operation at the same predetermined timing of the reference frequency Fs, which is the timing to drive the second output chopping switch 172 at the input of the first integrator 13. Additionally, the control circuit 12 performs the chopping operation of the input chopping switch 170 and the first output chopping switch 171 at a frequency of Fs/2, which is half the frequency of the first control signal ϕ1 of the reference frequency Fs.

The control circuit 12 modulates the input signals Vinp and Vinm by chopping at the input of the capacitive coupling amplifier 11 with the input chopping switch 170, and demodulates by chopping at the output of the capacitive coupling amplifier 11 with the first output chopping switch 171. Furthermore, the control circuit 12 captures the demodulated output signal of the capacitive coupling amplifier 11 into the first integrator 13 using the second output chopping switch 172.

Due to this circuit operation, the output signal repeatedly changes between positive and negative, causing the DC value to converge to the average value. This allows the influence of the offset of the first operational amplifier OP1 within the capacitive coupling amplifier 11 to be canceled out at the output of the capacitive coupling amplifier 11. As a result, even if the first integrator 13 becomes sensitive to errors dependent on the input voltage of the first integrator 13, it will no longer be affected by them. Therefore, the influence of offset can be reduced for the entire circuit.

In addition, the chopping operation frequency Fs/2 of the input chopping switch 170 and the first output chopping switch 171 before and after the capacitive coupling amplifier 11 is set lower than the reference frequency Fs of the chopping operation of the first integrator 13 and the second integrator 14. The drive frequency of the input chopping switch 170 and the first output chopping switch 171 can be lowered. An anti-aliasing filter may be provided at the stage before the input terminals Ina and Inb. The anti-aliasing filter includes an RC low-pass filter including a resistor and a capacitor.

Since the drive frequencies of the input chopping switch 170 and the first output chopping switch 171 are lowered, it is possible to lower the amount of current flowing through the resistors included in the anti-aliasing filter. It is possible to reduce detection errors due to voltage drops caused by such resistors. Additionally, according to this embodiment, the phases of the control signals ϕ1din and ϕ1dout are made the same, and the phases of the control signals ϕ2din and ϕ2dout are also made the same, making it easier to generate the control signals ϕ1din, ϕ1dout, ϕ2din, and ϕ2dout.

### Fourth Embodiment

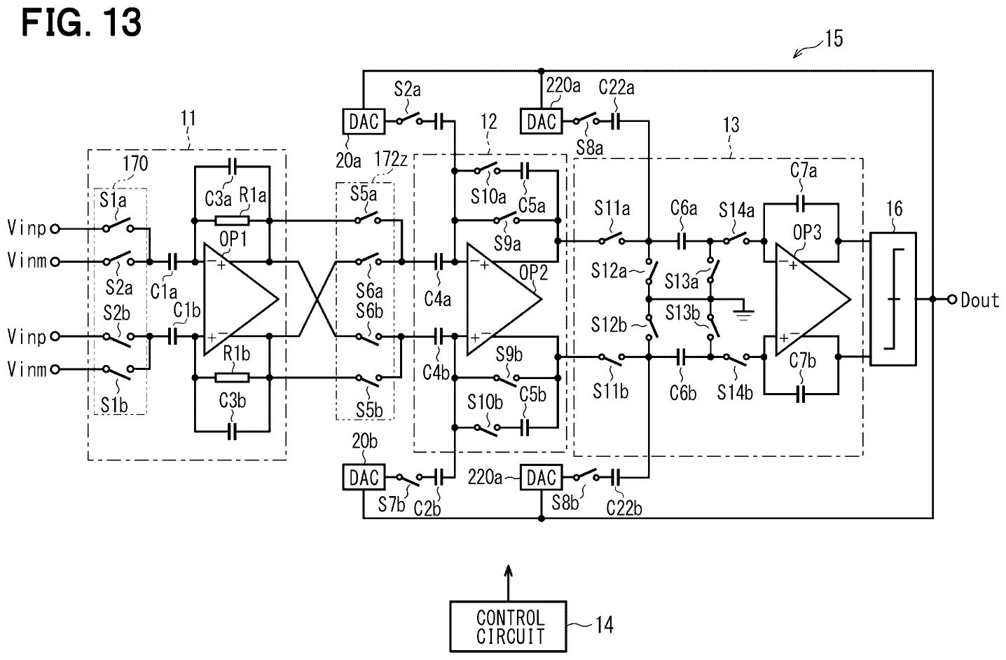

The following describes a fourth embodiment with reference to FIGS. 13 to 15. Hereinafter, differences from the third embodiment will be described. The difference from the third embodiment lies in the omission of the configuration corresponding to the first output chopping switch 171.

In the circuitry structure in FIG. 13, the respective functions of the switches S3a and S5a illustrated in FIG. 9 are integrated into the switch S5a, and the respective functions of the switches S3b and the S5b are integrated into the switch S5b. In addition, the respective functions of the switches S4b and S6a illustrated in FIG. 9 are integrated into the switch S6a, and the respective functions of the switches S4a and the S6b are integrated into the switch S6b. This means that only one output chopping switch 172z is connected between the capacitive coupling amplifier 11 and the first integrator 13.

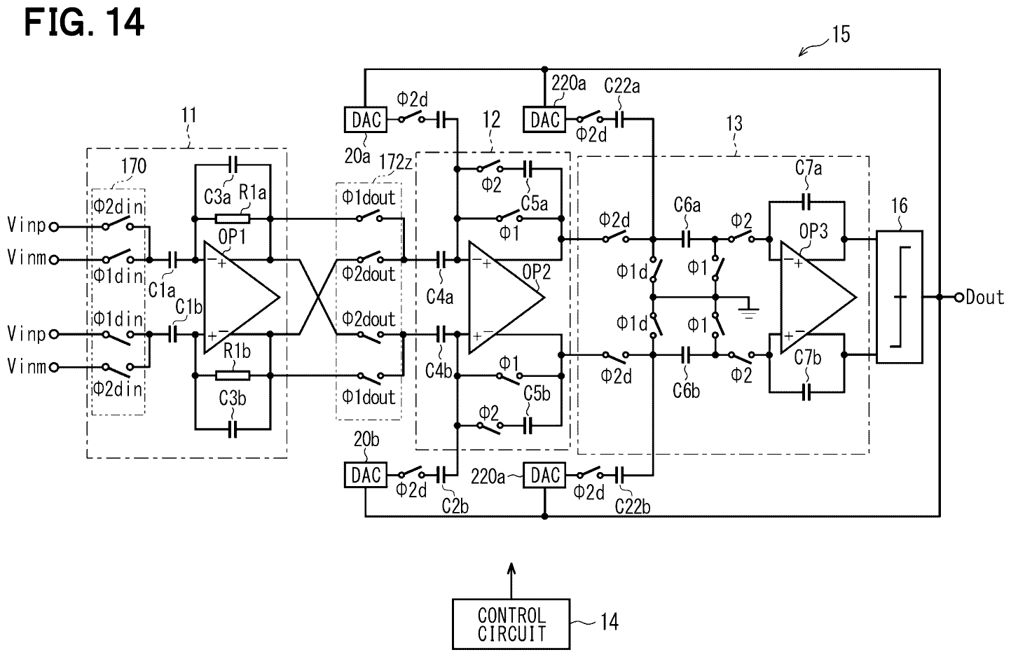

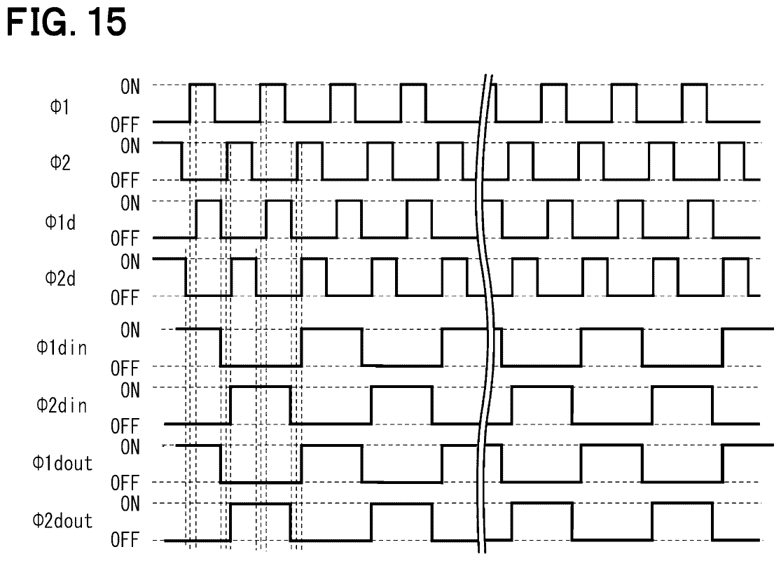

In this embodiment, the connections of components are modified as shown in FIG. 13; and the control signals for respective switches shown in FIG. 11 are changed as shown in FIG. 15, and are provided to switches as shown in FIG. 14.

When the control circuit 12 drives the first integrator 13 by the first control signal ϕ1 with the predetermined phase timing of the reference frequency Fs, the input chopping switch 170 is operated chopping at a frequency Fs/2, which is one-half of the reference frequency Fs. The control circuit 12 also operates the output chopping switch 172z at a chopping frequency of Fs/2, which is one-half the reference frequency Fs, and at a timing that is 90° out of phase with the driving timing of the input chopping switch 170.

According to this embodiment, the input signals Vinp and Vinm are modulated by chopping at the input of the capacitive coupling amplifier 11 using the input chopping switch 170. Additionally, demodulation is performed by chopping at the output of the capacitive coupling amplifier 11 using the output chopping switch 172z. The demodulated output signal of the capacitive coupling amplifier 11 is then captured by the first integrator 13. Even in such a configuration, the same effect as that of the third embodiment can be obtained.

According to the structure illustrated in FIG. 13 related to the present embodiment, the respective functions of the switches S3a, S5a illustrated in FIG. 9 related to the preceding embodiment can be integrated into one switch S5a, and the respective functions of the switches S3b, S5b illustrated in FIG. 9 can be integrated into one switch S5b. In addition, the respective functions of the switches S4b, S6a illustrated in FIG. 9 are integrated into the switch S6a, and the respective functions of the switches S4a, S6b illustrated in FIG. 9 are integrated into the switch S6b. Therefore, in this embodiment, as shown in FIG. 14, the output chopping switch 172z, which includes the switches S5 and S6, is switched by control signals ϕ1dout and ϕ2dout. Thus, it is possible that the first integrator 13 captures the demodulated output signal from the capacitive coupling amplifier 11.

In the present embodiment, the switches S3a, S3b, S4a, and S4b can be eliminated as compared to the third embodiment. The switches S3a, S3b, S4a, and S4b described in the third embodiment respectively adopt the MOS transistors. Therefore, an error factor may occur due to the on-resistance when the MOS transistors are turned on. Since the switches S3a, S3b, S4a, and S4b can be eliminated in the present embodiment, it is possible to optimally suppress the influence of change in on-resistance of the MOS transistors.

### Fifth Embodiment

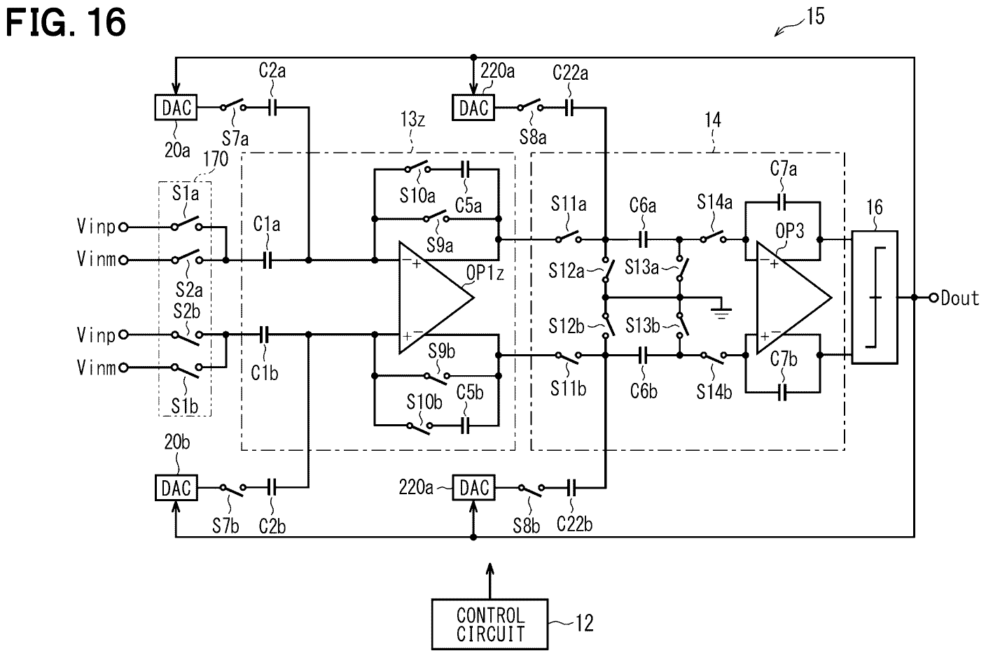

The following describes a fifth embodiment with reference to FIGS. 16 to 18. In this embodiment, the first stage is provided with the first integrator 13z, and it is applied to a configuration that omits the capacitive coupling amplifier 11. As shown in FIG. 16, the first integrator 13z as the main circuit unit includes a first operational amplifier OP1z and the feedback capacitor C5 (C5a, C5b) that is connected between the input and output of the first operational amplifier OP1z. The second integrator 14 is provided at the rear stage of the first integrator 13z, and the quantizer 16 is provided after the second integrator 14.

The first integrator 13z is constructed by a correlated double sampling (CDS) integrator. This integrator includes the feedback capacitor C5 (having capacitors C5a and C5b) and a feedback switch S10 (having switches S10a and S10b) in a series circuit connected between the input and output of the first operational amplifier OP1z. The first integrator 13z also includes a reset switch S9 (having switches S9a and S9b) that connects the input and output of the first operational amplifier OP1z. The output of the first operational amplifier OP1z, which is included in the first integrator 13z, includes the first common-mode feedback circuit CMFB1 as shown in FIG. 1. Since this is similar to the previously described embodiment, the explanation is omitted.

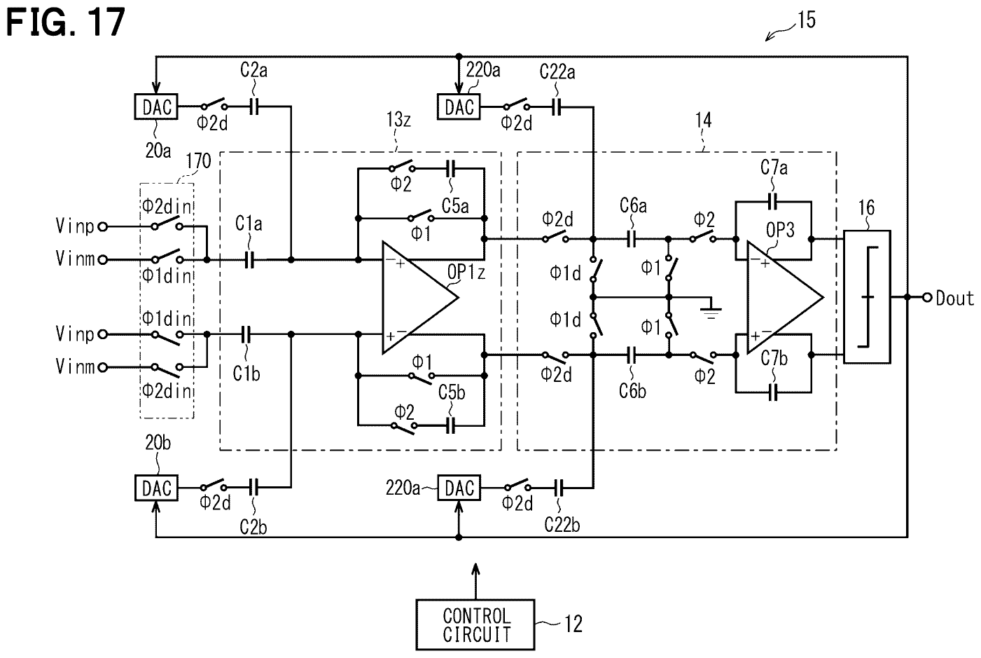

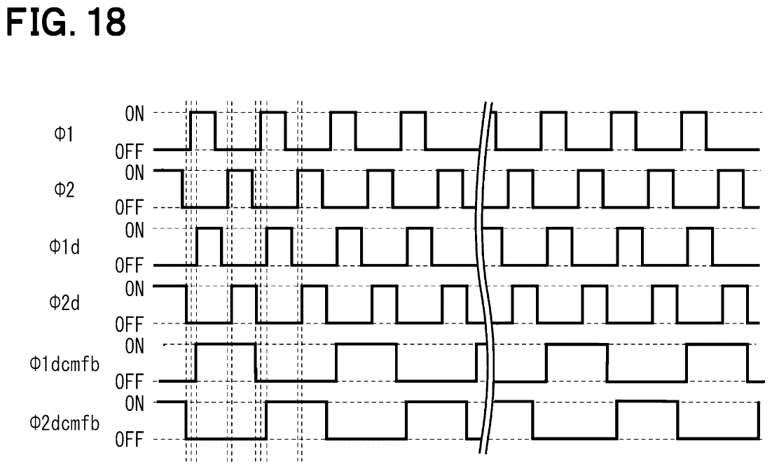

In such a configuration, when the first integrator 13z operates at the reference frequency Fs, it is possible to operate the first common-mode feedback circuit CMFB1 of the first integrator 13z at a frequency (for example, Fs/2) that is half of the reference frequency. The control signals ϕ1, ϕ2, ϕ1d, ϕ2d, ϕ1din, and ϕ2din applied to each switch are shown in FIG. 17. Furthermore, the relationship between the control signals ϕ1, ϕ2, ϕ1d, ϕ2d and the control signals ϕ1dcmfb, ϕ2dcmfb applied to the first common-mode feedback circuit CMFB1 is shown in FIG. 18.

By turning the first common-mode feedback circuit CMFB1 on and off with the control signals ϕ1dcmfb and ϕ2dcmfb shown in FIG. 18, it can operate at a frequency of Fs/2, which is one-half of the reference frequency Fs, thereby achieving the same operational effects as the first embodiment.

### Sixth Embodiment

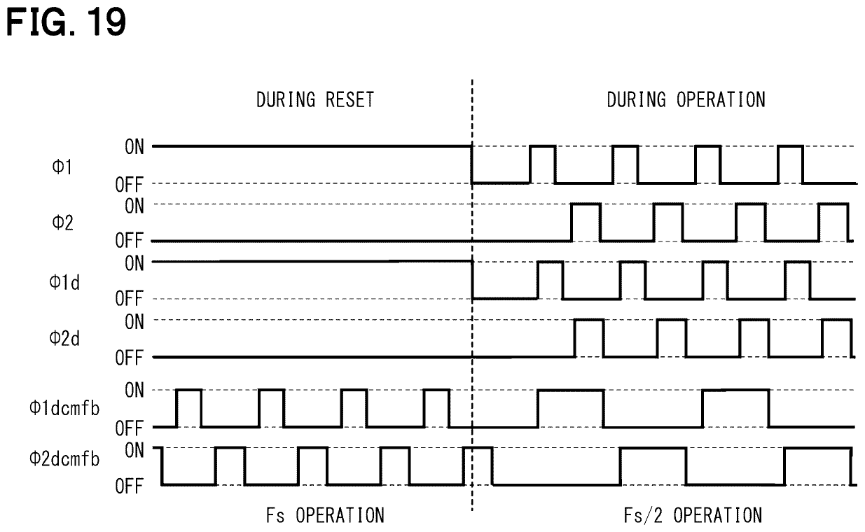

The following describes a sixth embodiment with reference to FIG. 19. In the sixth embodiment, the case where the same circuit configuration as in the fifth embodiment is applied will be described. During the period when the delta-sigma modulator 15 shown in FIG. 17 is operating normally, the first common-mode feedback circuit CMFB1 operates in the same manner as in the fifth embodiment by switching its operating frequency to Fs/2, which is one-half of the reference frequency Fs, thereby enabling accurate charge transfer between the first integrator 13z and the second integrator 14.

During the period when the normal operation is being reset, as shown in FIG. 19, the control circuit 12 keeps the control signals ϕ1 and ϕ1d turned on, while keeping the control signals ϕ2 and ϕ2d turned off. This allows the integration operation of the first integrator 13z to be stopped and the charge transfer to the second integrator 14 to be blocked, thereby resetting to the normal operation.

At this time, it is possible for the control circuit 12 to switch the first common-mode feedback circuit CMFB1 at the reference frequency Fs. By operating at the reference frequency Fs during the reset, the first common-mode feedback circuit CMFB1 operates at high speed. Therefore, the potential for current biasing Vbias can then be quickly returned to the ideal common-mode value.

### Other Embodiments

The present disclosure is not limited to the embodiments described above. For example, following modifications or extensions may be made. That is, two or more embodiments described above may be combined to implement the control of the present disclosure. A part of the above-described embodiment may be omitted as long as the difficulty can be solved, and may provide an example embodiment. In addition, various modifications of the present disclosure may be considered as encompassed in the present disclosure, as long as such modifications pertain to the gist of the present disclosure.

Although the present disclosure is described based on the above embodiments, the present disclosure is not limited to the disclosure of the embodiment and the structure. The present disclosure is intended to cover various modification examples and equivalents thereof. In addition, various modes/combinations, one or more elements added/subtracted thereto/therefrom, may also be considered as the present disclosure and understood as the technical thought thereof.

What is claimed is:

1. A switched capacitor circuit comprising:
a main circuit including
a sampling capacitor configured to sample an input signal by turning on an input chopping switch with a first control signal and a second control signal, the first control signal and the second control signal being different from each other,
an operational amplifier, and
a common-mode feedback circuit having
a first switch group,
a second switch group,
a first capacitor connected between an output of the operational amplifier and a node to which a current-biasing potential is applied from the operational amplifier,
a second capacitor connected in parallel to the first capacitor via the first switch group,
a third capacitor connected in parallel to the first capacitor via the second switch group,
a third switch group configured to apply an output common-mode reference potential and a current-biasing reference potential of the operational amplifier to the second capacitor, and
a fourth switch group configured to apply the output common-mode reference potential and the current-biasing reference potential of the operational amplifier to the third capacitor; and
a control circuit configured to
turn on the first switch group and the fourth switch group in synchronization with a first common control signal provided based on the first control signal, and
turn on the second switch group and the third switch group in synchronization with a second common control signal provided based on the second control signal, wherein
a value of total connected capacitance, which is acquired by connecting the output of operational amplifier to one of the first capacitor, the second capacitor, and the third capacitor of the common-mode feedback circuit, is same in both of a timing in which the first common control signal is at an on-level and a timing in which the second common control signal is at an on-level.

2. The switched capacitor circuit according to claim 1, wherein
the main circuit is a capacitive coupling amplifier including a feedback capacitor connected between an input of the operational amplifier and the output of the operational amplifier, and is configured to amplify the input signal.

3. The switched capacitor circuit according to claim 2, further comprising:
an integrator connected after the capacitive coupling amplifier, wherein
the control circuit is configured to:
control at least the common-mode feedback circuit not to be operated in an integration period during which an output of the capacitive coupling amplifier is integrated by the integrator, the output of the capacitive coupling amplifier serving as an input signal to the integrator, and
allow an operation of the common-mode feedback circuit in a period different from the integration period.

4. The switched capacitor circuit according to claim 3, wherein
the control circuit is configured to control the common-mode feedback circuit to be operated with a clock signal at one-half of a reference frequency, on a condition that the control circuit controls the integrator to be operated with a clock signal at the reference frequency.

5. The switched capacitor circuit according to claim 4, wherein
the control circuit is configured to control the capacitive coupling amplifier to be operated with a clock signal at one-half of the reference frequency.

6. The switched capacitor circuit according to claim 5, wherein
the operational amplifier is a first operational amplifier,
the integrator is a correlated double sampling integrator including:
a second operational amplifier;
a series circuit in which a feedback capacitor and a feedback switch are connected in series between an input of the second operational amplifier and an output of the second operational amplifier; and
a reset switch connecting the input of the second operational amplifier to the output of the second operational amplifier.

7. The switched capacitor circuit according to claim 5, wherein
the operational amplifier is a first operational amplifier,
the integrator includes a second operational amplifier and a second common-mode feedback circuit,
the second common-mode feedback circuit includes:
a fifth switch group;
a sixth switch group;
a fourth capacitor connected between an output of the second operational amplifier and a node to which a current-biasing potential is applied from the second operational amplifier;
a fifth capacitor connected in parallel to the fourth capacitor via the fifth switch group;
a sixth capacitor connected in parallel to the fourth capacitor via the sixth switch group;
a seventh switch group configured to apply the output common-mode reference potential and a current-biasing reference potential of the second operational amplifier to the fifth capacitor; and
an eighth switch group configured to apply the output common-mode reference potential and the current-biasing reference potential of the second operational amplifier to the sixth capacitor, and
the control circuit configured to:
turn on the fifth switch group and the eighth switch group in synchronization with the first common control signal provided based on the first control signal;
turn on the sixth switch group and the seventh switch group in synchronization with the second common control signal provided based on the second control signal; and
control the second common-mode feedback circuit of the integrator to be operated with a clock signal at one-half of the reference frequency, on a condition that the integrator is operated with a clock signal at the reference frequency.

8. The switched capacitor circuit according to claim 6, further comprising:
an output chopping switch located between the capacitive coupling amplifier and the integrator, wherein
the control circuit is configured to:
execute modulation by controlling a chopping operation of the input chopping switch for a signal at an input of the capacitive coupling amplifier and execute demodulation by controlling a chopping operation of the output chopping switch for an output signal at an output of the capacitive coupling amplifier; and
feed a demodulated output signal of the capacitive coupling amplifier into the integrator, the demodulated output signal acquired by the demodulation of the output signal, and
on a condition that control circuit drives the integrator with the first control signal at a predetermined phase timing of the reference frequency,
the chopping operation of the input chopping switch is executed at one-half of the reference frequency; and
the chopping operation of the output chopping switch is executed at one-half of the reference frequency and at a phase being 90 degrees out of phase with respect to a timing for driving the input chopping switch.

9. The switched capacitor circuit according to claim 6, further comprising:
a first output chopping switch connected between the capacitive coupling amplifier and the integrator; and
a second output chopping switch connected between the first output chopping switch and an input of the integrator, wherein
the control circuit is configured to:
execute modulation by controlling a chopping operation of the input chopping switch for a signal at an input of the capacitive coupling amplifier and execute demodulation by controlling a chopping operation of the first output chopping switch for an output signal at an output of the capacitive coupling amplifier; and
feed a demodulated output signal of the capacitive coupling amplifier into the integrator by controlling a chopping operation of the second output chopping switch, the demodulated output signal acquired by the demodulation of the output signal, and
on a condition that the control circuit drives the integrator with the first control signal at a predetermined phase timing of the reference frequency,
the chopping operation of the second output chopping switch at the input of the integrator is executed at a predetermined timing of the reference frequency, which matches a timing for driving the integrator; and
the chopping operation of the input chopping switch and the chopping operation of the first output chopping switch are executed at one-half of the reference frequency of the first control signal.

10. The switched capacitor circuit according to claim 1, wherein
the main circuit includes an integrator having a feedback capacitor connected between an input of the operational amplifier and the output of the operational amplifier.

11. The switched capacitor circuit according to claim 10, wherein
the common-mode feedback circuit of the integrator operates at one-half of a reference frequency, in a case where the integrator operates at the reference frequency.

12. The switched capacitor circuit according to claim 11, wherein
the integrator is a correlated double sampling integrator including:
the operational amplifier;
a series circuit in which a feedback capacitor and a feedback switch are connected in series between the input of the operational amplifier and the output of the operational amplifier; and
a reset switch connecting the input of the operational amplifier to the output of the operational amplifier.

13. The switched capacitor circuit according to claim 6, wherein
the control circuit is configured to:
execute switching of the common-mode feedback circuit at the reference frequency, in a period during which the switched capacitor circuit is being reset to a normal operation; and
execute switching of the common-mode feedback circuit at an operating frequency being one-half of the reference frequency, in a period during which the switched capacitor circuit is in the normal operation.
